(19) United States
(12) Patent Application Publication
(10) Pub. No.: US 2026/0366161 A1
(43) Pub. Date: Nov. 19, 2026

(54) WAFER SUPPORT FOR CYCLIC THERMAL EPITAXY

(71) Applicant: Applied Materials, Inc., Santa Clara, CA (US)

(72) Inventor: Errol Antonio C. SANCHEZ, Tracy, CA (US)

(21) Appl. No.: 19/208,375

(22) Filed: May 14, 2025

(51) Int. Cl. C23C 16/46; C23C 16/458

(52) U.S. Cl. CPC C23C 16/466; C23C 16/4581

(57) ABSTRACT

Embodiments herein provide a substrate support assembly including an outer assembly and an inner assembly. The outer assembly includes a support cylinder configured to support a substrate and an outer stem coupled to the support cylinder. The inner assembly includes a gas distribution plate configured to be disposed within the support cylinder and having a plurality of flow-directing features for directing gases to the substrate. The inner assembly further includes a base coupled to the gas distribution plate, wherein the base and the gas distribution plate at least partially define an interior volume therebetween. The inner assembly still further includes an inner stem coupled to the base and configured to provide a fluid conduit for flowing gases to the interior volume and through the flow-directing features of the gas distribution plate.

### INTRODUCTION

### Field

The present disclosure relates to semiconductor processing chambers, and more particularly, to apparatuses and methods for improved thermal control of semiconductor substrates during semiconductor processing operations.

### Description of the Related Art

Epitaxial (epi) deposition processes are widely used in semiconductor manufacturing to form high-purity, crystalline layers on semiconductor wafers. These processes are often performed at high temperatures (e.g., greater than 750 °C) and involve a series of temperature cycling steps, with temperature swings ranging from 70 °C to 200 °C or more, repeated over ten or more cycles. Achieving high throughput and consistent film quality in such demanding thermal environments presents several technical challenges. Therefore, a need exists for improved process chamber components and processing methods.

One requirement is the ability to rapidly and repeatably ramp wafer temperatures up and down throughout the process cycle. Slow wafer cooldown rates directly limit process throughput and can lead to non-uniform deposition across wafers, adversely affecting epitaxial film quality and overall device performance. Furthermore, accurate and responsive temperature control is essential for maintaining tight process windows and ensuring cycle-to-cycle repeatability.

Thus, there is a need for improved systems and methods that enable fast, repeatable thermal ramping and cooling with enhanced temperature control responsiveness and accuracy.

### SUMMARY

The present disclosure relates to semiconductor processing chambers, and more particularly, to apparatuses and methods for improved thermal control of semiconductor substrates during semiconductor processing operations.

In one or more embodiments, a processing chamber is provided, the processing chamber including: a chamber body at least partially defining an internal volume; and a substrate support assembly at least partially disposed within the internal volume, the substrate support assembly including: an outer assembly, the outer assembly including: a support cylinder configured to support a substrate on a top surface of the support cylinder; and an outer stem coupled to the support cylinder and configured to support the support cylinder in the internal volume; and an inner assembly, the inner assembly including: a gas distribution plate configured to be disposed within the support cylinder and including a plurality of flow-directing features for directing gases to the substrate supported on the support cylinder; a base coupled to the gas distribution plate, wherein the base and the gas distribution plate at least partially define an interior volume therebetween; and an inner stem coupled to the base and configured to provide a fluid conduit for flowing gases to the interior volume and through the flow-directing features of the gas distribution plate.

In one or more embodiments, a substrate support assembly is provided, the substrate support assembly including: an outer assembly, the outer assembly including: a support cylinder configured to support a substrate on a top surface of the support cylinder; and an outer stem coupled to the support cylinder and configured to support the support cylinder; and an inner assembly, the inner assembly including: a gas distribution plate configured to be disposed within the support cylinder and including a plurality of flow-directing features for directing gases to the substrate supported on the support cylinder; a base coupled to the gas distribution plate, wherein the base and the gas distribution plate at least partially define an interior volume therebetween; and an inner stem coupled to the base and configured to provide a fluid conduit for flowing gases to the interior volume and through the flow-directing features of the gas distribution plate.

In one or more embodiments, a substrate support assembly is provided, the substrate support assembly including: an outer assembly, the outer assembly including: a support cylinder configured to support a substrate on a top surface of the support cylinder; and an outer stem coupled to the support cylinder via a plurality of arms and configured to support the support cylinder, wherein the outer assembly is configured to be rotated about a central axis and translated vertically; and an inner assembly, the inner assembly including: a gas distribution plate configured to be disposed within the support cylinder and including a plurality of flow-directing features for directing gases to the substrate supported on the support cylinder; a base coupled to the gas distribution plate, wherein the base and the gas distribution plate at least partially define an interior volume therebetween; and an inner stem coupled to the base and configured to provide a fluid conduit for flowing gases to the interior volume and through the flow-directing features of the gas distribution plate, wherein the inner assembly is configured to be translated vertically to adjust a relative position of the inner assembly relative to the outer assembly.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a partial schematic side cross-sectional of a processing chamber, according to one or more embodiments.

FIG. 2 is a partial schematic side cross-sectional view of substrate support assembly, according to one or more embodiments.

FIGS. 3A-3C are partial schematic side cross-sectional views of the gas distribution plate 182 and the base 184 at a coupling point therebetween, according to one or more embodiments.

FIG. 4 shows a top-down planar top view of an exemplary arrangement of the gas distribution plate 182, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to semiconductor processing chambers, and more particularly, to apparatuses and methods for improved thermal control of semiconductor substrates during semiconductor processing operations.

Cyclic epitaxial deposition is a process technique used in semiconductor fabrication to grow high-quality crystalline layers through repeated cycles of precursor exposure and thermal treatment. Unlike continuous epitaxy, cyclic methods involve alternating deposition and surface conditioning steps—often with significant temperature swings—to enhance layer uniformity, dopant control, and interface quality. These cycles are typically repeated multiple times to achieve desired film thickness and material characteristics.

Thermal management and process stability is important to overall cyclic epitaxial deposition performance and yield. Thus, a key requirement for cyclic epitaxial deposition processes is the ability to rapidly and consistently ramp wafer temperatures up and down throughout each process cycle. Insufficient cooldown rates can significantly constrain process throughput and contribute to non-uniform deposition across wafer surfaces, ultimately degrading epitaxial layer quality and device performance. In addition, precise and responsive temperature control is important to maintaining narrow process windows and ensuring high cycle-to-cycle repeatability.

While conventional epitaxial process chambers typically employ thermal lamps for actively heating wafers during processing, such chambers often employ passive cooling means to cool the same. For example, conventional epitaxial process chambers often include a wafer support structure having a ceramic plate upon which the wafer rests during processing. Wafer cooling via ceramic plates relies on passive heat transfer. Because these ceramic plates typically have substantial thermal mass, they retain heat and cool down slowly. And, since the wafer is in direct contact with the plate, its cooling rate is tied to the plate's cooldown profile. As a result of the plate's limited ability to cool the wafer quickly through passive means, cooldown times between cycles are prolonged, reducing overall process throughput. While thinner plates can be used to decrease thermal mass and accelerate cooling, such designs are susceptible to mechanical deformation or fracture under the extreme thermal cycling conditions typical of cyclic epitaxial processes. This creates a tradeoff between thermal performance and mechanical durability that current systems struggle to resolve.

In addition to the above, many conventional epitaxial process chambers rely on pyrometry to monitor wafer temperature and control processing conditions. However, the pyrometers are often arranged to directly sample the backside of a ceramic plate upon which the wafer is supported. This approach presents several challenges. First, unwanted deposition on or near pyrometry viewports can obstruct their optical path, degrading the accuracy and reliability of temperature measurements. Maintaining a consistent or known emissivity on the sampled surfaces, such as those on the ceramic plate supporting the wafer or on the wafer itself, requires preventing or minimizing deposition on those surfaces. Furthermore, intimate contact and thermal coupling between the ceramic plate support and the wafer are almost impossible and variable, so that the measured temperature does not reflect the actual thermal or material conditions occurring on the wafer. Consequently, such indirect pyrometry can fail to capture temperature variations that affect wafer deposition behavior. Taken together, these factors render existing cooldown and temperature control approaches inefficient, unreliable, and ill-suited for the stringent demands of advanced cyclic epitaxial deposition processes.

The present disclosure addresses the limitations of conventional epitaxial process chambers in supporting high-throughput cyclic epitaxial deposition by introducing active means for wafer cooling. Unlike traditional systems that rely solely on passive heat dissipation through high-mass ceramic supports, the disclosed approach enables faster and more controlled thermal transitions between deposition cycles. By incorporating active cooling mechanisms that maintain compatibility with metal-free environments, the disclosed system enhances wafer temperature ramp-down rates, improves process repeatability, and mitigates issues related to thermal lag and non-uniform deposition. This active cooling strategy is particularly advantageous in processes requiring frequent and precise thermal cycling, thereby improving overall process efficiency and product quality.

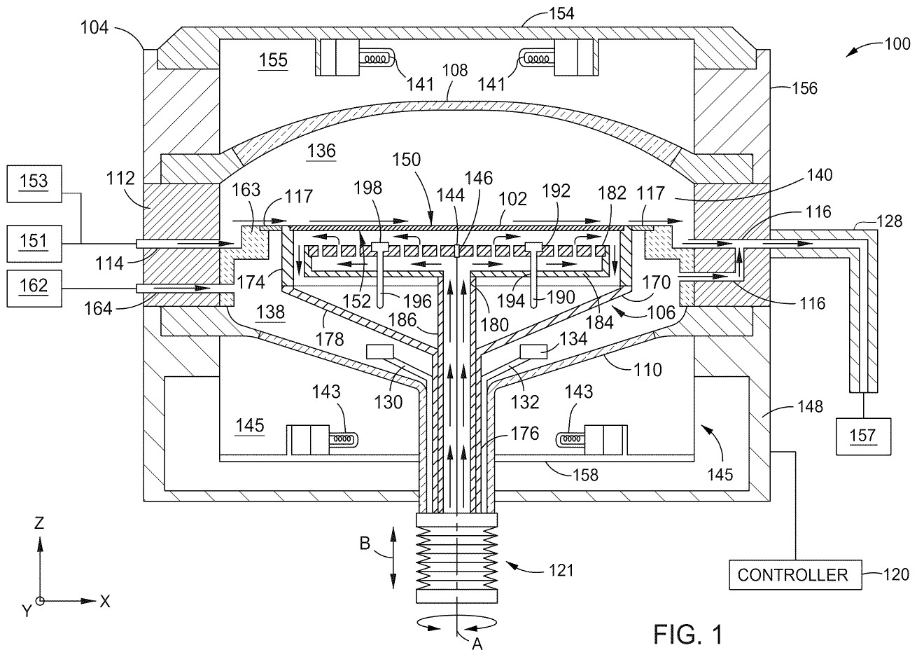

FIG. 1 is a partial schematic side cross-sectional view of a processing chamber 100, according to one or more embodiments. The processing chamber 100 is a deposition chamber. In one or more embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102. The processing chamber 100 is shown in a processing condition, or mode, in FIG. 1.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body 104. Disposed within the chamber body 104 is a substrate support assembly 106, an upper window 108 (such as an upper dome), a lower window 110 (such as a lower dome), a plurality of upper heat sources 141, and a plurality of lower heat sources 143. As shown, a controller 120 is in communication with the processing chamber 100 and is used to control processes and methods, such as the operations of the methods described herein. The present disclosure contemplates that each of the heat sources described herein can include one or more of: lamp(s), resistive heater(s), light emitting diode(s) (LEDs), and/or laser(s). The present disclosure contemplates that other heat sources can be used.

The plurality of upper heat sources 141 are disposed between the upper window 108 and a lid 154. The plurality of upper heat sources 141 form a portion of the upper heat source module 155. The lid 154 may include a plurality of sensors (not shown) disposed therein or thereon for measuring the temperature within the processing chamber 100. The plurality of lower heat sources 143 are disposed between the lower window 110 and a floor 158. The plurality of lower heat sources 143 form a portion of a lower heat source module 145. In one or more embodiments, the upper window 108 is an upper dome and is formed of an energy transmissive material, such as quartz. In one or more embodiments, the lower window 110 is a lower dome and is formed of an energy transmissive material, such as quartz.

An upper process volume 136 and a lower process volume 138 (e.g., a purge volume) are formed between the upper window 108 and the lower window 110. The upper process volume 136 and the lower process volume 138 together form an internal volume 140 defined at least partially by the upper window 108, the lower window 110, and one or more liners 163.

The substrate support assembly 106 is disposed in the internal volume 140 between the upper window 108 and the lower window 110. In one or more embodiments, one or more components of the substrate support assembly 106 partially define, and or separate, the upper process volume 136 and the lower process volume 138.

The substrate support assembly 106 includes an outer assembly 170 and an inner assembly 180 configured to cooperatively support, manipulate, and actively cool the substrate 102 during processing. The outer assembly 170 includes a support cylinder 174 adapted to support the substrate 102 in a generally horizontal orientation within the upper process volume 136. In one or more embodiments, the support cylinder 174 is mechanically coupled to an outer stem 176, which extends downwardly from the support cylinder 174 and through the floor 158 and/or lower body 148. The outer stem 176 is operatively engaged with a motion assembly 121, which includes one or more actuators positioned below the processing chamber 100 and configured to rotate (e.g., about a longitudinal axis “A”) and/or vertically displace (e.g., as indicated by the vertical arrows “B”) the outer stem 176, thereby enabling controlled rotational and translational motion of the support cylinder 174 during deposition processes. One or more arms 178 extend radially from the outer stem 176 and mechanically couples the outer stem 176 to the support cylinder 174, providing structural support and distributing mechanical loads to maintain planar alignment of the substrate 102.

Note that although described as an outer stem 176, the term “outer stem” is intended to broadly encompass any type of structure, linkage, or intermediary element configured to couple or connect the support cylinder 174 to the motion assembly 121, and is not limited to any particular geometry, material, or structural configuration.

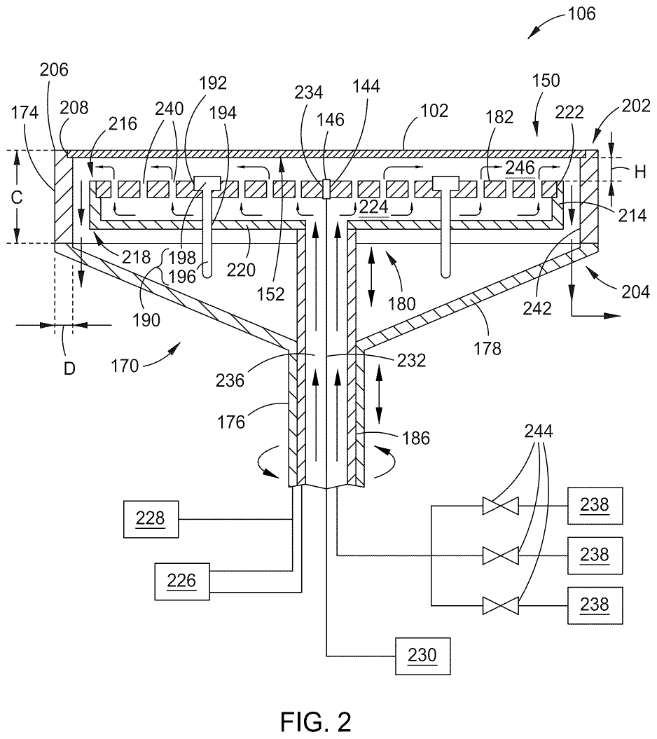

The inner assembly 180 includes a gas distribution plate 182, a base 184, and an inner stem 186. The gas distribution plate 182 and the base 184 are configured to be disposed within, or radially inward of, the support cylinder 174, while the inner stem 186 can extend through the outer stem 176. As described in further detail with reference to FIG. 2, the inner stem 186, the base 184, and the gas distribution plate 182 are together configured to direct cooling gases from one or more cooling gas sources toward a bottom surface 152 of the substrate 102 when the substrate is disposed on the support cylinder 174 during processing to enable faster and more controlled thermal transitions between epitaxial deposition cycles. The inner stem 186, like the outer stem 176, is operatively engaged with one or more actuators of the motion assembly 121 to facilitate at least vertical displacement the inner stem 186, thereby enabling controlled translational motion of the base 184 and the gas distribution plate 182 during deposition processes.

Note that although described as an inner stem 186, the term “inner stem” is intended to broadly encompass any type of structure, linkage, or intermediary element configured to couple or connect the gas distribution plate 182 and/or base 184 to the motion assembly 121, and is not limited to any particular geometry, material, or structural configuration.

A plurality of lift pins 190 is disposed through corresponding lift pin perforations 192 and 194 formed in the gas distribution plate 182 and the underlying base 184, respectively. Each lift pin 190 includes a rod portion 196 configured to be vertically translated through the gas distribution plate 182 and the base 184, enabling movement toward or away from the bottom surface 152 of the substrate 102. The lift pins 190 can be actuated, for example, by a translatable lift mechanism 130 disposed beneath the substrate support assembly 106, to selectively raise the substrate 102 from the support cylinder 174 for transfer out of the processing chamber 100, or to lower the substrate 102 onto the support cylinder 174 during transfer into the processing chamber 100. In addition or as an alternative thereto, the lift pins 190 can be actuated via vertical translation of the inner assembly 180 by the motion assembly 121. Each lift pin 190 further includes a head portion 198 having a greater diameter (or width) than the rod portion 196, wherein the head portion 198 is configured to rest upon an upper surface of the gas distribution plate 182 when the lift pin 190 is in a retracted or inactive position. In this configuration, the rod portion 196 extends downwardly through the gas distribution plate 182 and the base 184, while the head portion 198 prevents downward movement beyond the gas distribution plate 182, maintaining the lift pin 190 in a ready position for subsequent activation.

In one or more embodiments, the lift mechanism 130 includes a plurality of arms 132 that each include a lift pin pad 134 on which the rod portion 196 of at least one of the plurality of lift pins 190 can rest when the substrate support assembly 106 is lowered (e.g., lowered from a process position to a transfer position). In one or more embodiments, the lift mechanism 130, and/or the lift pin pads 134, is integrated into the arm(s) 178, rather being disposed below the inner assembly 180 and/or outer assembly 170.

The inner assembly 180 is further configured to accommodate at least one pyrometer 144 for sensing a temperature of the substrate 102 during processing. In one or more embodiments, an optical sensing head 146 of the pyrometer 144 is supported by the gas distribution plate 182 and is aimed upwards at the bottom surface 152 of the substrate 102 disposed on the support cylinder 174. The pyrometer 144 is configured to measure temperature emitted from the bottom surface 152 in real-time to facilitate real-time control of processing conditions of the processing chamber 100 by the controller 120.

The flow module 112 (which can define at least part of one or more sidewalls of the processing chamber 100) includes a plurality of gas inlets 114, a plurality of purge gas inlets 164, and one or more gas exhaust outlets 116 (two are shown in FIG. 1, each in fluid communication with one of the upper process volume 136 or the lower process volume 138). The plurality of gas inlets 114 and the plurality of purge gas inlets 164 are disposed on the opposite side of the flow module 112 from the one or more gas exhaust outlets 116. One or more lateral flow guides 117 are disposed adjacent the plurality of gas inlets 114 and the one or more gas exhaust outlets 116. The one or more lateral flow guides 117 are disposed above the purge gas inlets 164 and help to channel, or guide, gases flowed from the plurality of gas inlets 114 in a laminar, uniform direction right over the top surface 150 of the substrate 102. The one or more liners 163 are disposed on an inner surface of the flow module 112 and protects the flow module 112 from reactive gases used during deposition operations and/or cleaning operations. In one or more embodiments, the lateral flow guides 117 are coupled to, and/or extend inwardly from, the one or more liners 163. In one or more embodiments, the lateral flow guides 117 and/or the one or more liners 163 are annular in shape.

The gas inlet(s) 114 are each positioned to flow a gas parallel to the top surface 150 of a substrate 102 disposed within the upper process volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157.

One or more process gases supplied using the one or more process gas sources 151 can include one or more reactive gases (such as one or more of silicon (Si), phosphorus (P), boron (B) and/or germanium (Ge) containing gases) and/or one or more carrier gases (such as one or more of nitrogen (N₂) and/or hydrogen (H₂)). One or more purge gases supplied using the one or more purge gas sources 162 can include one or more inert gases (such as one or more of argon (Ar), helium (He), hydrogen (H₂) and/or nitrogen (N₂)). One or more cleaning gases supplied using the one or more cleaning gas sources 153 can include one or more of hydrogen (H) and/or chlorine (Cl). In one or more embodiments, the one or more process gases include Bdiborane (B2H6) and/or phospine (PH₃), and the one or more cleaning gases include hydrochloric acid (HCl).

The one or more gas exhaust outlets 116 are further connected to or include an exhaust system 128. The exhaust system 128 fluidly connects the one or more gas exhaust outlets 116 and the exhaust pump 157. The exhaust system 128 can assist in the controlled deposition of a layer on the substrate 102. The exhaust system 128 is disposed on an opposite side of the processing chamber 100 relative to the flow module 112.

During a deposition operation (e.g., an epitaxial growth operation), one or more process gases flow through the gas inlet(s) 114 and into the upper process volume 136 to flow over the substrate 102. During the deposition operation, one or more purge gases flow through the purge gas inlet(s) 164 and into the lower process volume 138. The one or more purge gases flow simultaneously with the flowing of the one or more process gases. The one or more process gases and the one or more purge gases are exhausted through the one or more gas exhaust outlets 116. In one or more embodiments, the one or more purge gases can be separately exhausted through one or more gas exhaust outlets 116 that are separate from the gas exhaust outlet(s) 116 used for exhausting the one or more process gases.

FIG. 2 is a partial schematic side cross-sectional view of the substrate support assembly 106, according to one or more embodiments. The substrate support assembly 106 is configured to support the substrate 102 in a deposition chamber. In one or more embodiments, the substrate support assembly 106 is a substrate support for use in an epitaxial deposition chamber, wherein an epitaxial film can be grown on the substrate 102. The processing chamber 100 creates a cross-flow of precursors across a top surface 150 of the substrate 102. The processing chamber 100 is shown in a processing condition, or mode, in FIG. 1.

As noted above, the substrate support assembly 106 includes the outer assembly 170 and the inner assembly 180 configured to cooperatively support, manipulate, and actively cool the substrate 102 during processing. The outer assembly 170 includes the support cylinder 174, which is configured to retain and stabilize the substrate 102 during processing (e.g., cyclic thermal epitaxial deposition processes). The support cylinder 174 is generally cylindrical or annular in shape, with a top end 202 and a bottom end 204 that are both open. One or more components of the inner assembly 180 may be configured to translate through the bottom end 204 of the support cylinder 174. Generally, the support cylinder 174 has greater lateral dimensions than the gas distribution plate 182, the base 184, and the inner stem 186 of the inner assembly 180.

In one or more embodiments, the support cylinder 174 has a height “C” of between about 10 mm and about 100 mm, such as between about 10 mm and about 50 mm, such as between about 15 mm and about 30 mm. However, other heights C for the support cylinder 174 are also contemplated. In one or more embodiments, the support cylinder 174 has a thickness “D” of between about 2 mm to 6 mm, for example. However, other thicknesses D for the support cylinder 174 are also contemplated.

The support cylinder 174 is composed of a thermally and chemically stable material, such as graphite, silicon carbide, coated or non-coated quartz, ceramic (such as alumina or aluminum nitride), or other high-performance, non-metallic material(s) capable of withstanding the elevated temperatures and reactive environments typical of epitaxial growth techniques. A top and/or inner surface 206 of the support cylinder 174 includes one or more substrate mounting features 208 configured to securely hold and align the substrate 102 in a fixed and predetermined orientation on the support cylinder 174 during processing, thereby enabling uniform exposure to precursor gases or other reactants. Further, the substrate mounting features 208 can provide lateral support and positional constraint for the substrate 102, preventing unwanted movement or misalignment of the substrate 102 during thermal cycling or rotation. In one or more embodiments, the substrate mounting features 208 include an annular ledge or shoulder disposed along the top and/or inner surface 206 of the support cylinder 174 and dimensioned to conform to the geometry of the substrate 102. In one or more embodiments, the ledge or shoulder can be recessed relative to an uppermost portion of the top and/or inner surface 206, thereby forming a seat that partially encloses an outer edge of the substrate 102 while maintaining exposure of the top surface 150 to the deposition environment of the upper process volume 136. In one or more embodiments, the substrate mounting features 208 include tabs or other protrusions extending upward from the top and/or inner surface 206. In one or more embodiments, the substrate mounting features 208 are designed to optimize heat dissipation and temperature around the edge of the substrate 102, thereby minimizing epitaxial growth non-uniformities at the edge(s) of the substrate 102.

In one or more embodiments, a side or bottom surface of the support cylinder 174 is mechanically coupled to the outer stem 176 via the arm(s) 178. In one or more embodiments, the outer stem 176 mechanically supports the support cylinder 174 within the internal volume 140. In one or more embodiments, the outer stem 176 and/or the arm(s) 178 are formed of quartz, graphite, silicon carbide, ceramic (such as alumina or aluminum nitride), or other non-metallic materials. In one or more embodiments, the outer stem 176 projects through an opening in the processing chamber 100 and is operatively engaged with the motion assembly 121 for imparting rotational and vertical motion on at least the support cylinder 174. Note that although described as being supported and/or actuated by mechanical means, the support cylinder 174 can also be supported and/or actuated by a magnetic levitation (maglev) or magnetic suspension system in one or more embodiments. In such examples, the outer stem 176 can be magnetically engaged with the motion assembly 121 so that the outer stem 176 does not need to project through an opening in the chamber body 104. Also note that the diameter of the outer stem 176 can be smaller, equal, or larger than the diameter of the support cylinder 174, depending at least on the design of the lower body 148, the lower window 110, the lower heat source module 145, and the floor 158, and, depending on the location and design of the motion assembly 121. Further, in one or more embodiments, the motion assembly 121 can be arranged on a side or a top of the chamber body 104 instead of being disposed centrally below the chamber body 104 as shown in FIGS. 1 and 2, such that the outer stem 176 extends laterally to the side of the chamber body 104.

The inner assembly 180 includes the gas distribution plate 182, the base 184, and the inner stem 186. The base 184 is generally cup-shaped and includes a cylindrical sidewall 214 defining an open top end 216 and a closed bottom end 218. The bottom end 218 of the base 184 is enclosed by a bottom plate 220, which is generally circular or disc-like in shape and extends transversely across the bottom end 218 of the sidewall 214. The bottom plate 220 is fixedly attached to the sidewall 214 of the base 184. In one or more embodiments, the bottom plate 220 is monolithically formed with the sidewall 214, such as through an integral machining or molding process. In alternative embodiments, the bottom plate 220 is joined to the sidewall 214 by any suitable mechanical coupling mechanism, including but not limited to welding, fastening (e.g., screws or bolts), press-fitting, etc.

Extending downwardly from the bottom plate 220 is the inner stem 186, which is also generally cylindrical. The inner stem 186 is affixed to a bottom or inner surface of the bottom plate 220 and projects downward through an opening in the processing chamber 100, thereby structurally supporting the inner assembly 180 within the processing chamber, while also providing a conduit 236 for electrical, thermal, and/or fluid communication.

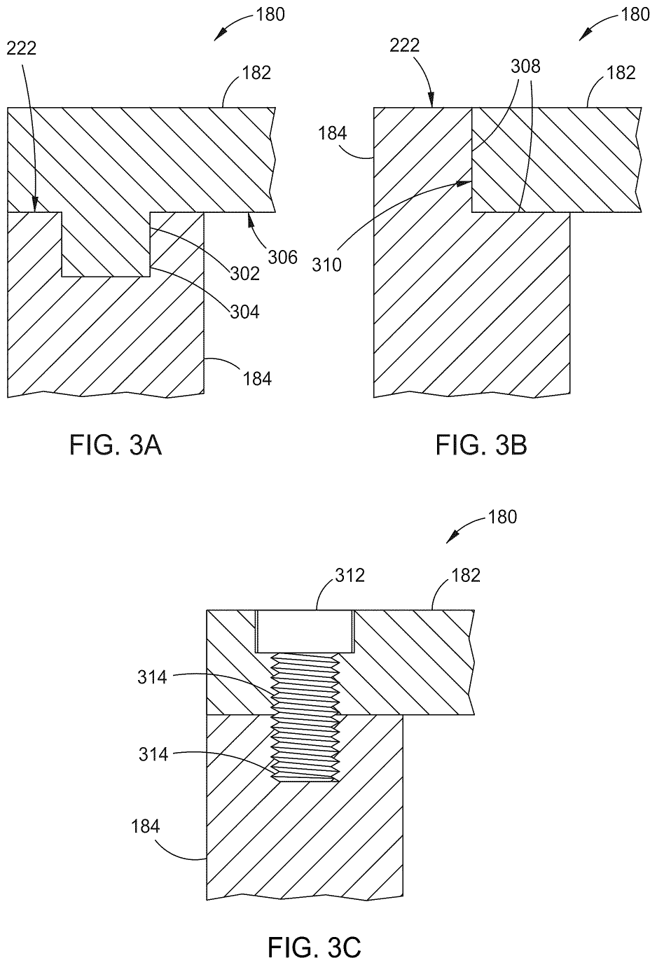

The top end 216 of the base 184 includes a top and/or inner surface 222, to which the gas distribution plate 182 is coupled. The gas distribution plate 182 is generally circular or disc-like in shape and extends across the top end 216 of the base 184, effectively enclosing an interior volume 224 of the base 184. The gas distribution plate 182 may be either fixedly or removably coupled to the top and/or inner surface 222. Any suitable mechanical coupling mechanism may be used to secure the gas distribution plate 182 to the top and/or inner surface 222, including threaded connections, snap-fit arrangements, clamping rings, or other fastening means. Exemplary coupling mechanisms are described in greater detail with reference to FIGS. 3A-3C.

While the inner assembly 180 has been described primarily with reference to a generally cylindrical, cup-shaped configuration including circular gas distribution and bottom plates, other shapes and configurations are also contemplated. For example, the base 184 may have a polygonal, elliptical, or irregular cross-sectional profile depending on design constraints or processing requirements. Likewise, the gas distribution plate 182 and bottom plate 220 need not be completely circular, and may instead be shaped to conform to non-cylindrical chamber geometries or to optimize gas flow patterns. In one or more embodiments, the gas distribution plate 182 is cup-shaped while the base 184 is disc-like, and the base 184 couples to the gas distribution plate 182 at an open bottom end of the gas distribution plate 182. In one or more further embodiments, the inner assembly 180 includes multiple gas distribution plates and/or surfaces and/or segmented or modular components for the base 184. Variations in the orientation, number, and arrangement of the inner stem 186 or other support members are also contemplated to accommodate different mounting schemes, actuator interfaces, or system architectures. Such alternative configurations are within the scope of the present disclosure and may be selected based on the specific processes performed, performance criteria, or manufacturing considerations.

In various embodiments, the base 184 and the gas distribution plate 182 of the inner assembly are fabricated from materials selected for their chemical resistance, thermal stability, and mechanical durability under the demanding conditions of semiconductor or industrial processing environments. Suitable materials include silicon carbide, quartz, graphite, ceramics (such as alumina or aluminum nitride), and other high-performance, non-metallic materials. These materials are particularly advantageous due to their resistance to corrosion by reactive process gases, low thermal expansion coefficients, and compatibility with high-temperature processing.

The base 184 and the gas distribution 182 plate may be formed from the same material or from different materials depending on performance requirements or manufacturing constraints. For example, the base 184 may be formed from a ceramic to provide mechanical rigidity and thermal insulation, while the gas distribution plate 182 may be fabricated from quartz or silicon carbide to ensure precise gas delivery and thermal uniformity. In one or more embodiments, composite or coated materials may also be used, such as a ceramic body with a silicon carbide coating to enhance surface durability. The selection of materials can be tailored to the specific process environment, including plasma exposure, thermal cycling, and chemical compatibility with the substrate 102 and/or reactants being used.

As noted above, in one or more embodiments, the outer stem 176 and/or the inner stem 186 is operatively coupled to the motion assembly 121, which can include one more translational and/or rotational actuators configured to impart motion on the stem(s) 176 and/or 186. In the illustrated example, both of the outer stem 176 and the inner stem 186 are acted upon by a translational actuator 226. Although illustrated as a single actuator, the translational actuator 226 can include a separate and distinct actuator for each of the outer stem 176 and the inner stem 186. Alternatively, both of the outer stem 176 and the inner stem 186 can be operatively coupled to the same translation actuator 226.

The translational actuator 226 is configured to impart independent translational motion to the outer stem 176 and the inner stem 186, thereby enabling controlled translation of the outer assembly 170 and the inner stem 186 within the processing chamber 100 to optimize thermal and reactant exposure conditions. The translational actuator 226 is mechanically linked to the outer stem 176 and the inner stem 186 in a manner that allows the outer stem 176 and the inner stem 186 to independently move vertically—i.e., along a direction generally perpendicular to a plane of the substrate 102 supported by the support cylinder 174, or a direction generally perpendicular to a plane of the bottom plate 220. The translational actuator 226 may include any suitable drive system capable of converting command signals from the controller 120 into precise mechanical motion. Exemplary actuators include, but are not limited to, electromechanical motors, linear actuators, servo-driven screw assemblies, pneumatic cylinders, hydraulic rams, or magnetically driven lift mechanisms. In all such embodiments, the translational actuator 226 receives position or motion commands from the controller 120, which may adjust the vertical position of the outer assembly 170 and the inner assembly 180 in real time based on process parameters, substrate handling operations, or system calibration procedures. Independent vertical translation may enable the support cylinder 174 to be brought into proximity with or spaced away from the upper window 108, or other component within the processing chamber 100, depending on the process requirements. Similarly, independent vertical translation may enable the gas distribution plate 182 to be brought into proximity or spaced away from the substrate 102 mounted on the support cylinder 174 during processing.

In the illustrated example, the outer stem 176 is further acted upon by a rotational actuator 228. The rotational actuator 228 is configured to impart controlled rotational motion of the outer stem 176, and thus the outer assembly 170 and substrate 102 supported thereon, about the central longitudinal axis A (shown in FIG. 1). Rotation of the substrate 102 during epitaxial deposition processes facilitates uniform distribution of precursor gases across the top surface 150 of the substrate 102, thereby promoting radial uniformity in layer thickness, composition, and crystalline quality of deposited epitaxial films. Continuous or periodic rotation of the substrate 102 further reduces the impact of localized thermal or flow non-uniformities within the processing chamber 100, resulting in improved symmetry and consistency of the epitaxial layer. In one or more embodiments where the outer stem 176 is configured to rotate and the lift mechanism 130 and/or the lift pin pads 134 are integrated into the arm(s) 178, rotation of the outer stem 176 can be coordinated such that the lift pin pads 134 are arranged at a specific orientation (via setting of flags or motor step counts by the controller 120) during substrate transfer to align the lift pin pads 134 and the lift pins 190.

In one or more embodiments, the outer stem 176 is acted upon by the rotational actuator 228, while the inner stem 186 is not (i.e., the outer stem 176 rotates while the inner stem 186 does not). In one or more other embodiments, both of the outer stem 176 and the inner stem 186 are acted upon by the rotational actuator 228. In one or more embodiments, the actuators 226, 228 are configured for independent or synchronized operation under programmable control by the controller 120 to accommodate various process parameters and/or substrate geometries.

Also shown in FIG. 2 is the pyrometer 144 for sensing temperature at the bottom surface 152 of the substrate 102. The pyrometer 144 includes the optical sensing head 146, a detector 230, and an optical fiber 232 optically coupling the optical sensing head 146 and the detector 230. The optical sensing head 146 is supported by the gas distribution plate 182 within a port 234 formed in the gas distribution plate 182, while the optical fiber 232 extends from the optical sensing head 146, through the conduit 236 of the inner stem 186, and to the detector 230. The detector 230 can be disposed outside of (e.g., below) the lower process volume 138 and/or the processing chamber 100. The pyrometer 144 is configured to measure temperature emitted from the bottom surface 152 in real-time to facilitate real-time control of processing conditions of the processing chamber 100 by the controller 120.

The interior volume 224 formed between, and at least partially defined by, the base 184 and the gas distribution plate 182 is in fluid communication with one or more gas sources 238 disposed outside of the processing chamber 100. The gas source(s) 238 is configured to supply at least a cooling gas for facilitating active substrate cooling during epitaxial deposition processes. The cooling gas may include, for example, an inert or thermally controlled gas such as hydrogen (H₂), helium (He) or nitrogen (N₂). Gases that are relatively inert up to a specific temperature but otherwise become more reactive above, such as dichlorosilane (DCS) and tetrachlorosilane (SiCl4), may also be used for cooling once the temperature has dropped below the specific temperature. In one or more embodiments, the gas source(s) 238 is configured to supply the cooling gas to the interior volume 224 via the conduit 236 and/or one or more other conduits through the inner stem 186. Accordingly, the conduit 236 and/or the one or more other conduits of the inner stem 186 provide a fluid pathway for the cooling gas from the gas source(s) 238 into the interior volume 224.

During and/or between processing operations, cooling gas is flowed into the interior volume 224 from the gas source(s) 238 (as indicated by arrows in FIG. 2), wherein the cooling gas disperses or substantially fills the interior volume 224. The gas distribution plate 182 is positioned above the interior volume 224 to receive the incoming cooling gas from the interior volume 224. The gas distribution plate 182 includes one or more flow-directing features 240, such as apertures, channels, or the like, that enable the controlled dispersion of the cooling gas from the interior volume 224 toward the substrate 102 positioned on the support cylinder 174. The cooling gas is thereby directed toward the bottom surface 152 of the substrate 102, where the cooling gas can form a gaseous blanket layer that cools the substrate 102 via convective heat transfer. Following contact with the bottom surface 152, the gas continues to flow outwardly (e.g., radially outward) along the bottom surface 152, after which an inner surface 242 of the support cylinder 174 directs the cooling gas downwards, around a circumferential edge of the gas distribution plate 182 and/or the base 184, and into the lower process volume 138. Accordingly, the gas distribution plate 182, the support cylinder 174, and the base 184 are arranged to create a flow path for cooling gases that extends from the interior volume 224, through the flow-directing features 240, outward along the bottom surface 152 of the substrate 102, and downwards around the circumferential edge of the gas distribution plate 182 and the base 184 within the support cylinder 174. The cooling gas can then exit the processing chamber 100 through the one or more gas exhaust outlets 116 positioned circumferentially around the internal volume 140.

In one or more embodiments, the gas source(s) 238 include a plurality of gas sources 238 as shown in FIG. 2 (three are shown). In such embodiments, each of the plurality of gas sources 238 can be configured to deliver a cooling gas at a distinct temperature, enabling thermal tuning of the gas environment delivered to the bottom surface 152 of the substrate 102. Further, each gas source can be operably coupled with an independently actuated valve 244, allowing for precise control over the flow rate and temperature composition of the cooling gases flowed to the substrate 102. By selectively adjusting these valves 244, the composition and thermodynamic properties of the cooling gas mixture may be dynamically modulated during operation, thereby enabling enhanced process uniformity, thermal management, or substrate cooling efficiency.

Even further, since the vertical position of the inner assembly 180 is independently adjustable relative to the outer assembly 170, and thus, relative to the substrate 102, a height H of a gap 246 between the gas distribution plate 182 and the bottom surface 152 of the substrate 102 (and/or the top and/or inner surface 206 of the support cylinder 174) can be controlled (e.g., modified) by vertically translating the inner assembly 180 and/or the outer assembly 170. This adjustability provides an additional process parameter for tuning cooling gas flow dynamics and thermal profiles. By varying the spacing between the gas distribution plate 182 and the substrate 102, the processing chamber 100 can modify convective heat transfer below the substrate 102, and thus, adjust a cooling rate of the substrate 102, offering enhanced control over substrate cooling rates between epitaxial deposition cycles, and also improved temperature uniformity during epitaxial growth. This vertical adjustability thus introduces an additional degree of freedom to optimize thermal ramping and cooling for cyclic thermal epitaxial deposition processes.

FIGS. 3A-3C are partial schematic side cross-sectional views of the gas distribution plate 182 and the base 184 at a coupling point (i.e., junction) therebetween, according to one or more embodiments. Each of FIGS. 3A-3C illustrate an exemplary coupling mechanism that can be used to secure the gas distribution plate 182 to the base 184. It should be understood that any suitable mechanical coupling mechanism may be used to attach the gas distribution plate 182 to the base, including combinations of the below-described features and/or other equivalent attachment means. The described embodiments are provided for illustrative purposes and are not intended to be limiting.

With reference to FIG. 3A, in one or more embodiments, the gas distribution plate 182 is mechanically attached to the top and/or inner surface 222 of the base 184 by engagement of complementary structural features. For example, in one or more embodiments, a recess 302 may be formed into the top and/or inner surface 222 of the base 184, the recess 302 being dimensioned to receive a corresponding protrusion 304 extending from a bottom and/or inner surface 306 of the gas distribution plate 182. Alternatively, the recess 302 may be formed in the gas distribution plate 182, while the protrusion 304 is formed on the base 184. The protrusion 304 may be retained within the recess 302 through a snap-fit, interference-fit, friction-fit, or similar engagement. In one or more embodiments, the interfacing components can be joined through welding, adhesive bonding, or other suitable securing methods, which can be in addition to the complementary structural features above.

Turning to FIG. 3B, in one or more embodiments, the top and/or inner surface 222 of the base 184 may include a stepped ledge 308 (e.g., a shoulder) configured to engage and support at least a portion of the gas distribution plate 182. For example, the stepped ledge 308 may receive a portion of an outer sidewall 310 and/or or the bottom surface 306 of the gas distribution plate 182, thereby providing alignment and positioning for the gas distribution plate 182 on the base 184. The gas distribution plate 182 may then be retained within the ledge 308 through an interference-fit or friction-fit configuration, or may be further secured by welding, adhesive, or other fastening techniques. Alternatively, the ledge 308 may be formed in the gas distribution plate 182 and configured to engage at least a portion of the top and/or inner surface 222 of the base 184.

With reference now to FIG. 3C, in one or more embodiments, mechanical fasteners 312 such as screws, bolts, or rivets may be employed to secure the gas distribution plate 182 to the base 184. Fastener receiving features 314, such as holes or slots, may be formed in both the gas distribution plate 182 and the base 184 to accommodate such mechanical fasteners 312. The mechanical fasteners 312 may extend through aligned fastener receiving features 314 in both the gas distribution plate 182 and the base 184 and be tightened to mechanically retain the components together.

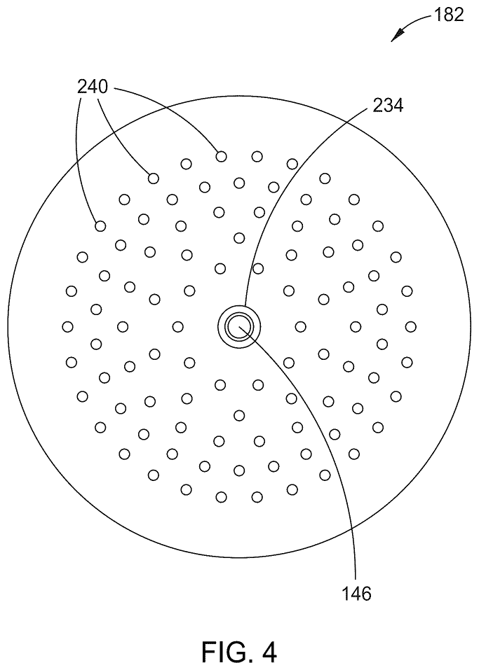

FIG. 4 shows a top-down planar top view of an exemplary arrangement of the gas distribution plate 182, according to one or more embodiments. As noted above, the gas distribution plate 182 is provided for guiding the flow of cooling gases toward the bottom surface 152 of the substrate 102 during epitaxial deposition processes. The gas distribution plate 182 is generally circular in shape, although other shapes—such as elliptical, quadrilateral, polygonal, or irregular geometries—are also contemplated.

The gas distribution plate 182 includes the port 234 configured to accommodate and/or support the optical sensing head 146 of the pyrometer 144 for in-situ temperature measurement of the substrate 102 during processing. The port 234 is sized and shaped to receive the optical sensing head 146 and is positioned such that the pyrometer 144 is oriented to face directly toward the bottom surface 152 of the substrate 102. In one or more embodiments, the port 234 is centrally disposed on the gas distribution plate 182. This arrangement enables the pyrometer 144 to obtain direct, accurate, real-time temperature measurements from a center of the bottom surface 152. While a single port 234 is illustrated at the center of the gas distribution plate 182, it is understood that any number of ports 234 may be provided, and may be positioned at any suitable location(s) along the gas distribution plate 182. This allows for the use of multiple pyrometers, where desired, to achieve enhanced spatial resolution of substrate temperature measurements or to accommodate various reactor designs and processing requirements.

A plurality of flow-directing features 240 is also formed in the gas distribution plate 182, and these flow-directing features 240 are configured to direct cooling gases toward the bottom surface 152 of the substrate 102 to flow against the bottom surface 152 and help regulate substrate temperature during deposition, and/or to facilitate active cooling of the substrate 102 between cycles of high temperature epitaxial deposition. The number, size, shape, and distribution of the flow-directing features 240 can vary depending on specific process parameters, such as target gas flow rate, pressure, deposition temperature, and/or the physical characteristics of the substrate 102, including its thickness and material composition. Generally, the flow-directing features 240 can include apertures, perforations, channels, or the like.

In one or more embodiments, a majority of the flow-directing features 240 are concentrated toward a center of the gas distribution plate 182, providing focused cooling for substrates 102 that exhibit greater thermal accumulation near the center. In other embodiments, the majority of flow-directing features 240 are positioned toward an outer perimeter of the gas distribution plate 182 to enhance edge cooling, which may be beneficial in mitigating temperature gradients across the substrate 102. The arrangement of the flow-directing features 240 can thus be tailored to promote uniform cooling by guiding the flow of cooling gases in a manner that impinges on the bottom surface 152 of the substrate 102 and then disperses radially outward. This controlled gas flow supports improved thermal management during epitaxial growth, contributing to enhanced film uniformity and reduced defect formation.

In one or more embodiments, the flow-directing features 240 are also strategically arranged to direct the flow of cooling gases toward and/or across the bottom surface 152 of the substrate 102 to establish a protective gaseous blanket or barrier layer that inhibits unwanted deposition of reactants and/or other process materials on the bottom surface 152, in addition to providing beneficial cooling of the substrate 102. By preventing such deposition, the bottom surface 152 of the substrate 102 can be maintained in a clean, controlled state, thereby preserving a consistent and known emissivity from the substrate 102. A stable emissivity is critical for enabling reliable, direct measurements of the substrate's temperature by the pyrometer 144 during processing, facilitating precise thermal management and process uniformity.

Accordingly, the systems and methods described herein provide improvements over conventional epitaxial process chambers and associated hardware by enabling high-throughput cyclic epitaxial deposition through the integration of active wafer cooling mechanisms. Unlike traditional approaches that depend solely on passive thermal dissipation via high-thermal-mass ceramic components, the disclosed embodiments facilitate faster and more controlled thermal transitions between deposition cycles. The incorporation of active cooling solutions—while maintaining compatibility with metal-free process environments—enhances wafer temperature ramp-down rates, improves process consistency, and reduces the effects of thermal lag and deposition non-uniformities. These advantages are particularly beneficial for applications requiring frequent and precise thermal cycling, ultimately contributing to increased process efficiency, yield, and product quality.

It is contemplated that one or more aspects disclosed herein may be combined. As an example, one or more aspects, features, components, operations and/or properties of the processing chamber 100 may and/or the substrate support assembly 106 be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

1. A processing chamber, the processing chamber comprising:
a chamber body at least partially defining an internal volume; and
a substrate support assembly at least partially disposed within the internal volume, the substrate support assembly comprising:
an outer assembly, the outer assembly comprising:
a support cylinder configured to support a substrate on a top surface of the support cylinder; and
an outer stem coupled to the support cylinder and configured to support the support cylinder in the internal volume; and
an inner assembly, the inner assembly comprising:
a gas distribution plate configured to be disposed within the support cylinder and comprising a plurality of flow-directing features for directing gases to a bottom surface of the substrate supported on the support cylinder;
a base coupled to the gas distribution plate, wherein the base and the gas distribution plate at least partially define an interior volume therebetween; and
an inner stem coupled to the base and configured to provide a fluid conduit for flowing the gases to the interior volume and through the flow-directing features of the gas distribution plate.

2. The processing chamber of claim 1, wherein the gas distribution plate, the support cylinder, and the base are arranged to create a flow path for the gases extending from the interior volume, through the flow-directing features, outward along the bottom surface of the substrate supported on the support cylinder, and downwards around a circumferential edge of the gas distribution plate and the base within the support cylinder.

3. The processing chamber of claim 2, wherein flowing the gases along the bottom surface of the substrate forms a gaseous blanket layer below the substrate that actively cools the substrate via convective heat transfer.

4. The processing chamber of claim 3, wherein:
the inner assembly and the outer assembly are independently configured to vertically translate within the internal volume; and
a spacing between the gas distribution plate and the top surface of the support cylinder can be modified via vertical translation of at least one of the inner assembly or the outer assembly.

5. The processing chamber of claim 4, wherein modification of the spacing between the gas distribution plate and the top surface of the support cylinder can adjust a cooling rate of the substrate via the gaseous blanket layer.

6. The processing chamber of claim 2, wherein flowing the gases along the bottom surface of the substrate forms a gaseous blanket layer below the substrate that prevents deposition on the bottom surface of the substrate.

7. The processing chamber of claim 2, further comprising one or more gas exhaust outlets positioned circumferentially around the internal volume and configured to exhaust the gases flowed downward around the circumferential edge of the gas distribution plate and the base.

8. The processing chamber of claim 1, wherein:
the inner assembly and the outer assembly are independently configured to vertically translate within the internal volume; and
the outer assembly is further configured to rotate within the internal volume.

9. The processing chamber of claim 1, wherein the support cylinder is formed of at least one of graphite, silicon carbide, quartz, alumina, or aluminum nitride.

10. The processing chamber of claim 1, wherein the gas distribution plate is formed of at least one of graphite, silicon carbide, quartz, alumina, or aluminum nitride.

11. The processing chamber of claim 1, further comprising a pyrometer disposed through the gas distribution plate and configured to capture direct temperature measurements of the bottom surface of the substrate supported on the support cylinder.

12. A substrate support assembly, the substrate support assembly comprising:
an outer assembly, the outer assembly comprising:
a support cylinder configured to support a substrate on a top surface of the support cylinder; and
an inner assembly, the inner assembly comprising:
a gas distribution plate configured to be disposed within the support cylinder and comprising a plurality of flow-directing features for directing gases to the substrate supported on the support cylinder; and
a base coupled to the gas distribution plate, wherein the base and the gas distribution plate at least partially define an interior volume therebetween.

13. The substrate support assembly of claim 12, wherein the gas distribution plate, the support cylinder, and the base are arranged to create a flow path for the gases extending from the interior volume, through the flow-directing features, outward along a bottom surface of the substrate supported on the support cylinder, and downwards around a circumferential edge of the gas distribution plate and the base within the support cylinder.

14. The substrate support assembly of claim 12, wherein:
at least one of the gas distribution plate or the base is disc-like in shape;
at least one of the gas distribution plate or the base is cup-shaped and comprises an open end; and
the gas distribution plate and the base are coupled to each other at the open end.

15. The substrate support assembly of claim 14, wherein the gas distribution plate is formed of at least one of graphite, silicon carbide, quartz, alumina, or aluminum nitride.

16. The substrate support assembly of claim 15, wherein the base is formed of at least one of graphite, silicon carbide, quartz, alumina, or aluminum nitride.

17. The substrate support assembly of claim 12, wherein the gas distribution plate further comprises:
a port centrally disposed through the gas distribution plate and configured to accommodate an optical sensing head of a pyrometer; and
the plurality of flow-directing features arranged around the port.

18. The substrate support assembly of claim 12, wherein:
the support cylinder comprises an open top end and an open bottom end; and
at least one of the gas distribution plate or the base can be vertically translated through the open bottom end of the support cylinder.

19. The substrate support assembly of claim 18, wherein the support cylinder is formed of at least one of graphite, silicon carbide, quartz, alumina, or aluminum nitride.

20. A substrate support assembly, the substrate support assembly comprising:
a support cylinder configured to support a substrate on a top surface of the support cylinder, wherein the support cylinder is configured to be rotated about a central axis and translated vertically;
a gas distribution plate configured to be disposed within the support cylinder and comprising a plurality of flow-directing features for directing gases to the substrate supported on the support cylinder;
a base coupled to the gas distribution plate, wherein the base and the gas distribution plate at least partially define an interior volume therebetween; and
an inner stem coupled to the base and configured to provide a fluid conduit for flowing gases to the interior volume and through the flow-directing features of the gas distribution plate, wherein the inner stem is configured to be translated vertically to adjust a relative position of the gas distribution plate relative to the substrate supported on the support cylinder.
